(19) United States
(12) Patent Application Publication
(10) Pub. No.: US 2026/0052805 A1
(43) Pub. Date: Feb. 19, 2026

(54) MICRO LED DISPLAY CHIP AND METHOD FOR ROUGHENING THE SAME

(71) Applicant: JADE BIRD DISPLAY (SHANGHAI) LIMITED, Shanghai (CN)

(72) Inventor: Jin CAO, Shanghai (CN)

(73) Assignee: JADE BIRD DISPLAY (SHANGHAI) LIMITED, Shanghai (CN)

(21) Appl. No.: 19/303,374

(22) Filed: Aug. 19, 2025

(30) Foreign Application Priority Data
Aug. 19, 2024 (CN) 202411142917.5

(51) Int. Cl. H10H 20/82; H10H 20/01; H10H 20/821

(52) U.S. Cl. CPC H10H 20/82; H10H 20/01335; H10H 20/017; H10H 20/0363; H10H 20/0364; H10H 20/821

(57) ABSTRACT

A micro LED display chip and a method for roughening the same, and the method includes providing a micro LED structure including a light emitting mesa, and the light emitting mesa has a surface including a light emitting surface; and performing a plasma bombardment on the light emitting surface using a first gas, and performing a dry etching treatment on the light emitting surface using a second gas, to form a roughened structure on the light emitting surface. The embodiments of the present disclosure can increase probability of photons' escape and improve light extraction efficiency.

### CROSS-REFERENCE TO RELATED APPLICATIONS

This application claims the benefit of priority to Chinese Patent Application No. 202411142917.5, filed on Aug. 19, 2024 with China National Intellectual Property Administration, and entitled “MICRO LED DISPLAY CHIP AND METHOD FOR ROUGHENING THE SAME”, the entire disclosure of which is incorporated herein by reference.

### FIELD

The present disclosure relates to the field of semiconductor manufacturing, and more particularly, to a micro LED display chip and a method for roughening the same.

### BACKGROUND

With gradual development of display technology, micro light emitting diode (LED) display chips, as semiconductor components having tiny sizes (e.g., less than 50 μm) and capable of emitting light, have increasingly become a trend of new display technology due to their low power consumption, long life, high brightness, high contrast and other advantages. Light emitting mesa is an important structure in micro LED display chips, and is particularly valued in light emitting effect thereof.

However, there is such a physical phenomenon that visible light is prone to total reflection at an interface when entering from an optically denser medium to an optically thinner medium, and a light emitting surface of the light emitting mesa has a large difference in refractive index. As a result, it is difficult for light to escape directly from the surface after total reflection. Moreover, even if the light escapes after multiple reflections, there is a problem of excessive light loss, which seriously reduces light extraction efficiency.

There is an urgent need for a method for roughening a micro LED display chip, which can adjust an optical path by roughening a light emitting surface, and can even change a propagation direction of an original total reflection light, to effectively increase probability of photons' escape and improve the light extraction efficiency.

### SUMMARY

The present disclosure provides a micro LED display chip and a method for roughening the same, to increase probability of photons' escape and improve the light extraction efficiency.

Embodiments of the present disclosure provide a method for roughening a light emitting surface of a micro LED display chip. The method includes providing a micro LED structure including a light emitting mesa, and the light emitting mesa has a surface including a light emitting surface; and performing a plasma bombardment on the light emitting surface using a first gas, and performing a dry etching treatment on the light emitting surface using a second gas, to form a roughened structure on the light emitting surface.

In some embodiments, a method for forming the light emitting mesa includes providing a substrate and forming on a first surface of the substrate a first confinement layer, a quantum well layer and a second confinement layer; etching, from the first surface of the substrate, the second confinement layer, the quantum well layer, and a part of a thickness of the first confinement layer, to obtain a light emitting mesa; and removing the substrate from a second surface of the substrate, and exposing a second surface of the first confinement layer, and the second surface of the substrate is opposite to the first surface of the substrate.

In some embodiments, before removing the substrate from the second surface of the substrate, the method for forming the light emitting mesa further includes forming a first bonding layer covering the substrate and the light emitting mesa from the first surface of the substrate; providing a driver chip with a second bonding layer on a first surface thereof; and bonding the first bonding layer and the second bonding layer.

In some embodiments, the method for forming the light emitting mesa further includes forming a microlens on a treated second surface of the first confinement layer.

In some embodiments, performing the plasma bombardment on the light emitting surface using the first gas, and performing the dry etching treatment on the light emitting surface using the second gas, to form the roughened structure on the light emitting surface, includes introducing the first gas and the second gas, to perform the plasma bombardment on the light emitting surface using the first gas, and perform the dry etching treatment on the light emitting surface using the second gas, and the light emitting surface has a surface roughness greater than or equal to a predetermined surface roughness threshold.

In some embodiments, a second RF power is adopted during a process of performing the plasma bombardment on the light emitting surface using the first gas and performing the dry etching treatment on the light emitting surface using the second gas, and a first RF power is adopted during a process of etching, from the first surface of the substrate, the part of the thickness of the first confinement layer; and the second RF power is less than the first RF power.

In some embodiments, a ratio of the first RF power to the second RF power ranges in [10,∞]; and/or, the second RF power ranges from 0 W to 10 W.

In some embodiments, performing the plasma bombardment on the light emitting surface using the first gas includes ionizing the first gas with a second ICP power, to obtain plasma of the first gas; using the plasma of the first gas to perform a plasma bombardment on the light emitting surface; and, a first ICP power is adopted during a process of etching, from the first surface of the substrate, the part of the thickness of the first confinement layer, and the second ICP power is greater than the first ICP power.

In some embodiments, a ratio of the second ICP power to the first ICP power ranges in [2,5]; and/or, the second ICP power ranges from 700 W to 1000 W.

In some embodiments, the first gas includes argon gas, and the plasma of the first gas is argon plasma.

In some embodiments, the first confinement layer is an N-type Group III-V compound layer, and the second gas contains Cl₂ and does not contain BCl₃.

In some embodiments, the first confinement layer is made of GaN, and the

following chemical reaction formula is used to perform the dry etching treatment on the light emitting surface using Cl₂:

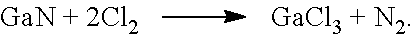

In some embodiments, Cl₂ at a first flow rate is used as an etching gas during a process of etching, from the first surface of the substrate, the part of the thickness of the first confinement layer, and Cl₂ in the second gas is at a second flow rate; and the second flow rate is less than the first flow rate.

In some embodiments, a ratio of the first flow rate to the second flow rate ranges in [1,4]; and/or, the second flow rate ranges from 30 sccm to 70 sccm.

The embodiments of the present disclosure further provide a micro LED display chip. The micro LED display chip includes a light emitting mesa including a light emitting surface. The light emitting surface has a roughened structure prepared by the method for roughening a light emitting surface of a micro LED display chip described above.

In some embodiments, the roughened structure is a nanoscale microstructure; and the roughened structure has a width ranging from 20 nm to 1000 nm, and/or, a height ranging from 20 nm to 1000 nm.

In some embodiments, the roughened structure has a shape of one or more selected from a group consisting of spherical shape, hemispherical shape, conical shape, pointed-conical shape, cylindrical shape, and rectangular shape.

The embodiments of the present disclosure have the following beneficial effects.

In the embodiments of the present disclosure, by performing a plasma bombardment on the light emitting surface using a first gas, and performing a dry etching treatment on the light emitting surface using a second gas, to form a roughened structure on the light emitting surface, it is possible to obtain a first confinement layer with a relatively large surface roughness, and realize a roughening treatment of the light emitting surface, which is conducive to adjusting the optical path, and even changing the propagation direction of the original total reflected light, to effectively increase the probability of photons' escape and improve the light extraction efficiency.

Further, by introducing the first gas and the second gas at the same time, to perform the bombardment and the etching treatment on the light emitting surface, the light emitting surface has a surface roughness greater than or equal to a predetermined surface roughness threshold. With the above embodiment, the optical path can be adjusted by roughening the light emitting surface, and the propagation direction of the original total reflected light can even be changed, and thus, the probability of photons' escape is effectively increased, and the light extraction efficiency is improved. In addition, the bombardment and the etching treatment are both dry treatments, which have better morphological controllability and better process stability than a wet roughening process. The bombardment and the etching treatment are mature and stable processes in terms of process cost control, and thus have lower process costs and complexity than those of a roughening process using nanocrystals and nanoparticles as masks.

Further, compared with an etching process for the first surface of the first confinement layer in a process of forming the light emitting mesa, a small RF power is adopted in a roughening process of the light emitting surface, and ion energy during the plasma bombardment can be reduced, and intensity of a physical bombardment of plasma can be reduced. Excessive physical bombardment may cause that the light emitting surface is bombarded and flattened, and adopting a small RF power will increase particle size obtained after roughening, making it rougher and more uneven. In addition, a roughening treatment process in the embodiments of the present disclosure includes two parts of physical bombardment and chemical etching, and thus, reducing the physical bombardment intensity is also equivalent to increasing intensity of the chemical dry etching treatment, which is conducive to further improving controllability and treatment effect of the roughening treatment.

Further, the ratio of the first RF power to the second RF power ranges in [10,00]; and/or, the second RF power ranges from 0 W to 10 W, and the second RF power is very small, or even close to or equal to zero. By adopting a very small second RF power, ionic energy during the plasma bombardment can be minimized, the intensity of the physical bombardment of the plasma can be reduced, to further increase the particle size obtained after the roughening treatment, and improve controllability of the roughening treatment.

Further, compared with the etching process for the first surface of the first confinement layer in the process of forming the light emitting mesa, a relatively large ICP power is adopted in the roughening process of the light emitting surface, and thus, more gas molecules can be ionized into plasma. The roughening treatment process in the embodiments of the present disclosure includes two parts of physical bombardment and chemical etching, increasing the ICP power can increase the number of ions in the plasma, and decomposed plasma can react with atoms or molecules of the light emitting surface. As a result, this is equivalent to increasing the intensity of the chemical dry etching treatment, which is conducive to further improving controllability and treatment effect of the roughening treatment.

Further, the first confinement layer is an N-type Group III-V compound layer, and the second gas contains Cl₂ and does not contain BCl₃. By using Cl₂, Group V atoms on a surface of the Group III-V compound layer (such as, nitrogen atoms on a surface of GaN) can be substituted by chlorine atoms, to be separated from a crystal lattice and form a Group V compound (such as, a nitride). Finally, the nitride and chloride can be separated from the surface of GaN together, to achieve an effect of GaN material being etched. In addition, by not containing BCl₃, the formed GaCl₃ can have a larger particle size and be rougher. Specifically, addition of BCl₃ will weaken a chemical factor in the etching process, thereby weakening selective etching of GaN and reducing a surface roughness of GaN.

Further, compared with the etching process for the first surface of the first confinement layer in the process of forming the light emitting mesa, a relatively smaller flow rate of Cl₂ as the etching gas is adopted in the roughening process of the light emitting surface, to reduce a speed of a chemical reaction. A slow etching reaction further makes the formed GaCl₃ have a larger particle size and rougher.

Further, a microlens is formed on a treated light emitting surface, and the roughened light emitting surface can be used as a refractive layer at the light emitting mesa interface, to better change the propagation direction of total reflected light, increase the probability of photons' escape, and improve the light extraction efficiency.

### BRIEF DESCRIPTION OF THE DRAWINGS

FIG. 1 is a schematic view of a total reflection optical path at an interface between optical material layers in the prior art.

FIG. 2 is a schematic flow chart of a method for roughening a micro LED display chip according to an embodiment of the present disclosure.

FIG. 3 to FIG. 9 are schematic structural section views of a device corresponding to various steps in a method for roughening a micro LED display chip according to an embodiment of the present disclosure.

### DESCRIPTION OF REFERENCE NUMERALS

Substrate 100, buffer layer 101, epitaxial layer 102, light emitting mesa 103, first confinement layer 1031, quantum well layer 1032, second confinement layer 1033, transparent conductive layer 104, passivation layer 105, first photoresist layer 161, first bonding layer 106, first conductive column 107, driver chip 200, conductive connector 201, second bonding layer 206, second conductive column 207, N-type electrode 301, P-type electrode 302, microlens 303.

### DETAILED DESCRIPTION

As the foregoing description, in existing micro LED display chips, the light emitting surface of the light emitting mesa has a large difference in refractive index. As a result, it is difficult for light to escape directly from the surface after total reflection. Moreover, even if the light escapes after multiple reflections, there is a problem of excessive light loss, which seriously reduces light extraction efficiency.

It has been found though research that, in the existing micro LED display chips, the light emitting surface in the light emitting mesa is often a smooth interface, which is prone to a problem of total reflection.

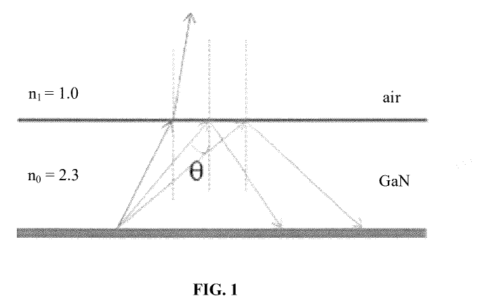

FIG. 1 is a schematic view of a total reflection optical path at an interface between optical material layers in the prior art.

As shown in FIG. 1, as an example, a light emitting surface of a light emitting mesa is made of gallium nitride (GaN), which may have a surface medium with a refractive index, also known as a refractive index n₀ of a material, of 2.3, and air has a refractive index n₁ of approximately 1.0.

Because there is such a physical phenomenon that visible light is prone to total reflection at an interface when entering from an optically denser medium to an optically thinner medium, and the light emitting surface in the light emitting mesa is often a smooth interface, the problem of total reflection is more likely to occur. It has been further found through research that, if the light emitting surface can be roughened, then it will be conducive to adjusting the optical path, and even changing the propagation direction of the original total reflected light, to effectively increase the probability of photons' escape and improve the light extraction efficiency.

In a research direction of roughening treatment, a surface to be treated can be cleaned by a wet roughening treatment method, for example, using potassium hydroxide (KOH) or sulfuric acid (H₂SO₄), to achieve an effect of roughening the surface to be treated.

It has been further found through research that, sizes of coarsened particles obtained by the above wet roughing treatment are relatively large, and thus, depth of roughened morphology and width of obtained particles cannot be effectively controlled, and roughening process is unstable, which can easily lead to deformation and distortion of roughened pattern, which is difficult to meet small size requirements of advanced technology.

In another research direction of roughening treatment, nanocrystals, nanoparticles and other structures can be used as a mask to form a pattern on a chip.

It has been further found through research that, the above roughening treatment method is very costly, has a complex process and a cumbersome post-processing, and is inconvenient.

In the embodiments of the present disclosure, by introducing the first gas and the second gas at the same time, to perform the bombardment and the etching treatment on the light emitting surface, the light emitting surface has a surface roughness greater than or equal to a predetermined surface roughness threshold. With the above embodiment, the optical path can be adjusted by roughening the light emitting surface, and the propagation direction of the original total reflected light can even be changed, and thus, the probability of photons' escape is effectively increased, and the light extraction efficiency is improved. In addition, the bombardment and the etching treatment are both dry treatments, which have better morphological controllability and better process stability than a wet roughening process. The bombardment and the etching treatment are mature and stable processes in terms of process cost control, and thus have lower process costs and complexity than those of a roughening process using nanocrystals and nanoparticles as masks.

In order to make the above-mentioned purposes, features and beneficial effects of the present disclosure more obvious and understandable, specific embodiments of the present disclosure will be described in detail below in conjunction with the accompanying drawings.

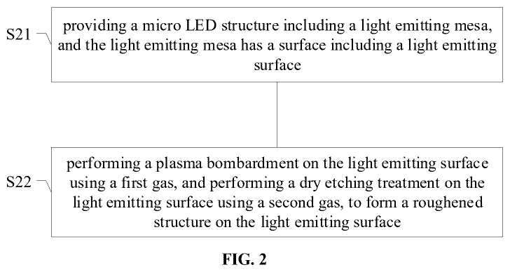

FIG. 2 is a schematic flow chart of a method for roughening a micro LED display chip according to an embodiment of the present disclosure. The method for roughening the micro LED display chip may include:
step S21: providing a micro LED structure including a light emitting mesa, and the light emitting mesa has a surface including a light emitting surface; and
step S22: performing a plasma bombardment on the light emitting surface using a first gas, and performing a dry etching treatment on the light emitting surface using a second gas, to form a roughened structure on the light emitting surface.

Each of the above steps will be illustrated below in conjunction with the accompanying drawings.

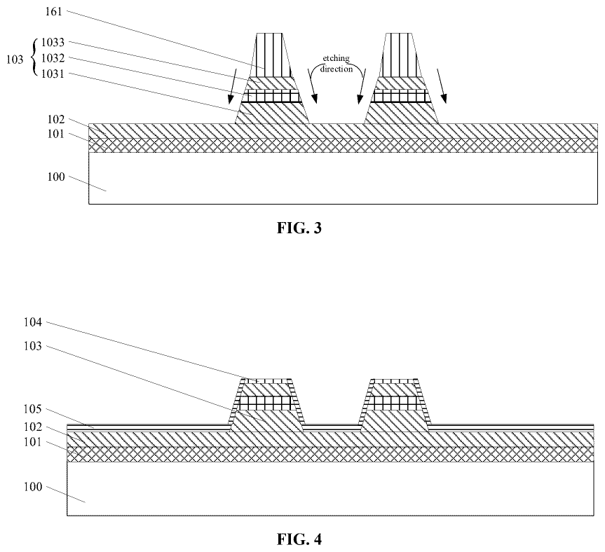

FIG. 3 to FIG. 9 are schematic structural section views of a device corresponding to various steps in a method for roughening a micro LED display chip according to an embodiment of the present disclosure.

As shown in FIG. 3, a substrate 100 is provided. A first confinement layer 1031, a quantum well layer 1032 and a second confinement layer 1033 are formed on a first surface of the substrate 100. The second confinement layer 1033, the quantum well layer 1032 and a part of a thickness of the first confinement layer 1031 are etched from the first surface of the substrate 100, to obtain a light emitting mesa 103.

Specifically, the substrate 100 may be provided. A buffer layer 101 may be formed on the substrate 100. And, a material layer of an epitaxial layer 102 may be formed on the buffer layer 101.

In some embodiments, the substrate 100 may, for example, include a sapphire substrate, etc., and have a composition containing alumina (Al₂O₃).

In some other embodiments, the substrate 100 may include a substrate of other appropriate materials, such as, a semiconductor substrate, such as a silicon substrate. The semiconductor substrate may further be made of a material including germanium, silicon germanium, silicon carbide, gallium arsenide or indium gallium. The semiconductor substrate may further be a silicon substrate on an insulator or a germanium substrate on an insulator, or a substrate with an epitaxial layer (Epi layer) grown.

In some embodiments, the epitaxial layer 102 may include one or more selected from a group consisting of the first confinement layer 1031, the quantum well layer 1032, and the second confinement layer 1033.

The first confinement layer 1031 may be an N-type Group III-V compound layer, and correspondingly, the second confinement layer 1033 may be a P-type Group III-V compound layer.

The quantum well layer 1032 may be a layer of a material suitable for forming a quantum well structure, such as, a layer of a Group III-V compound.

It should be pointed out that, the III-V compound layer refers to a material layer formed from a compound of an element selected from a group consisting of Group III elements and of an element selected from a group consisting of Group V elements, and the Group III elements may include, for example, B, Al, Ga, and In, the Group V elements may include N, P, As, and Sb.

In the embodiments of the present disclosure, the Group III-V compound layer may be selected and used according to specific requirements, and specific Group III-V compounds adopted in the first confinement layer 1031, the quantum well layer 1032 and the second confinement layer 1033 may be consistent or inconsistent.

In one specific embodiment, the Group III-V compound layer may be selected from a group consisting of GaN, GaAs and InP.

It should be pointed out that, the epitaxial layer 102 may further include other appropriate layers, such as, a sacrificial layer, or the like, and is not limited in specific structure herein.

In some embodiments, a material layer of a transparent conductive layer 104 (see FIG. 4) may further be formed on the material layer of the epitaxial layer 102, and then, the transparent conductive layer 104 may be etched together with the second confinement layer 1033.

Here, the transparent conductive layer 104 may be made of a material including indium tin oxide (In₂O₅Sn), to improve conductivity property and light emitting effect, and to reduce the ohmic effect.

It should be pointed out that, the material of the transparent conductive layer 104 may also include other appropriate materials, such as, fluorine-doped tin oxide (FTO), and zinc oxide (ZnO).

It should be pointed out that, in some embodiments, it is also possible to form a transparent conductive layer 104 on a top surface of the light emitting mesa 103 after etching the first confinement layer 1031, the quantum well layer 1032, and the second confinement layer 1033 to obtain the light emitting mesa 103. Therefore, in order to illustrate a process of forming the light emitting mesa 103 more clearly, the transparent conductive layer 104 is not shown in FIG. 3. However, this does not constitute a restriction on specific steps and processes for forming the transparent conductive layer 104.

In the embodiment shown in FIG. 3, a patterned first photoresist layer 161 may further be formed. The first photoresist layer 161 covers various light emitting mesas in a light emitting mesa region, and exposes a region between adjacent light emitting mesas.

Then, by using the first photoresist layer 161 to etch the second confinement layer 1033, the quantum well layer 1032 and the first confinement layer 1031, the second confinement layer 1033 and the quantum well layer 1032 in addition to the light emitting mesa can be removed, and a part of a thickness of the first confinement layer 1031 can be removed, to retain the second confinement layer 1033, the quantum well layer 1032, and the first confinement layer 1031 of the light emitting mesa.

Further, the second confinement layer 1033, the quantum well layer 1032, and the first confinement layer 1031 can be etched at an etching angle inclined inward and greater than 0, to obtain the sloped second confinement layer 1033, quantum well layer 1032, and first confinement layer 1031.

And, as shown in FIG. 3, the inclined inward indicates that an etching direction points from an oblique upper part near the center of the light emitting mesa 103 to diagonal down away from the center of the light emitting mesa 103.

In specific implementation, the etching angle inclined inward and greater than 0 can be formed by appropriate methods.

In some embodiments, the shape of slope collapse can be a patterned photoresist layer (such as, a first photoresist layer 161 shown in FIG. 3) shaped into slope.

In some other embodiments, a patterned photoresist layer with a conventional morphology can be formed. Then, gradually widening etching morphology can be achieved by adjusting a etching process parameter.

As shown in FIG. 4, the first photoresist layer 161 is removed, and a passivation layer 105 is formed. As previously mentioned, the transparent conductive layer 104 can further be formed.

And, the passivation layer 105 may be disposed on sidewall surfaces of various light emitting mesas 103 and a surface of the substrate 100, and top surfaces of the light emitting mesas 103 are exposed.

In some embodiments, the passivation layer 105 can further be formed into covering the substrate 100 and exposing the top surfaces of the light emitting mesas 103. In other words, the passivation layer 105 can cover the sidewall surfaces of the light emitting mesas 103.

And, the passivation layer 105 may be made from a material including a stack of one or more selected from a group consisting of a silicon oxide layer, an alumina layer, a silicon nitride layer, and a polyimide layer.

As shown in FIG. 5, a first bonding layer 106 is formed. The first bonding layer 106 covers the substrate 100 and the light emitting mesa 103 from the first surface of the substrate 100.

Specifically, the first bonding layer 106 may be formed on the substrate 100. A via may be formed in the first bonding layer 106. A first conductive column 107 may be formed in the via.

Specifically, a material layer of the first bonding layer 106 may be formed first, and then, the first bonding layer 106 is etched to form a via. The via of the first bonding layer 106 exposes a light reflection layer 111 on the top surfaces of the light emitting mesas 103 (in a case that a protective layer 105 is formed, the protective layer 105 may be penetrated and the light reflection layer 111 is exposed), and exposes a P-type electrode region.

In some embodiments, the substrate 100 may have one or more regions selected from a group consisting of an N-type electrode region for forming an N-type electrode, a P-type electrode region for forming a P-type electrode, and a display region for forming the light emitting mesas 103. It should be understood that, the substrate 100 may further have other appropriate regions.

And, the first conductive column 107 may be disposed on the light reflection layer 111 on the top surfaces of the light emitting mesas 103, and in the P-type electrode region of the substrate 100.

In one specific embodiment, the first conductive column 107 may be made from a material including a combination of one or more selected from a group consisting of copper, tungsten, aluminum, silver, platinum, and gold.

It should be understood that, a depth of the first conductive column 107 on the top surfaces of the light emitting mesas 103 and a depth of the first conductive column 107 in the P-type electrode region may be consistent.

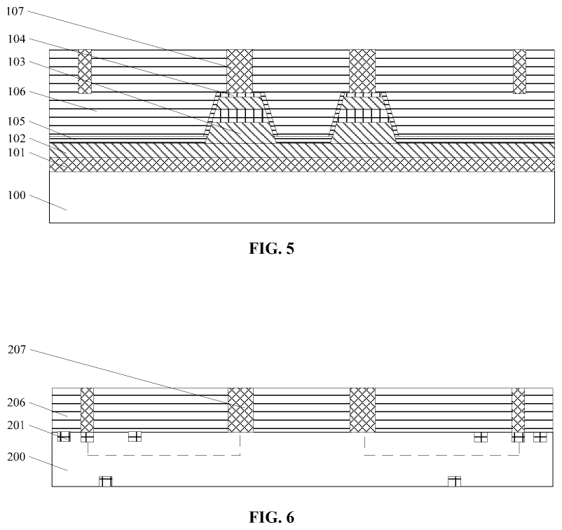

As shown in FIG. 6, a driver chip 200 is provided, and the driver chip 200 has a second bonding layer 206 on a first surface thereof.

Specifically, the driver chip 200 may be formed. A second bonding layer 206 may be formed on the driver chip 200. And, a second conductive column 207 may be formed in the second bonding layer 206.

And, a position of the second conductive column 207 and a position of the first conductive column 107 corresponds one by one.

Here, the driver chip 200 may be, for example, a thin film transistor (TFT) board or an integrated circuit (IC) board.

The driver chip 200 may have a conductive connector 201 therein, for example, may include a conductive interconnecting layer having a wire and a conductive plug.

In one specific embodiment, the second bonding layer 206 may be made from a material including a combination of one or more selected from a group consisting of silicon oxide, alumina, and silicon nitride.

The second conductive column 207 may be made from a material including a combination of one or more selected from a group consisting of copper, tungsten, aluminum, silver, platinum, and gold.

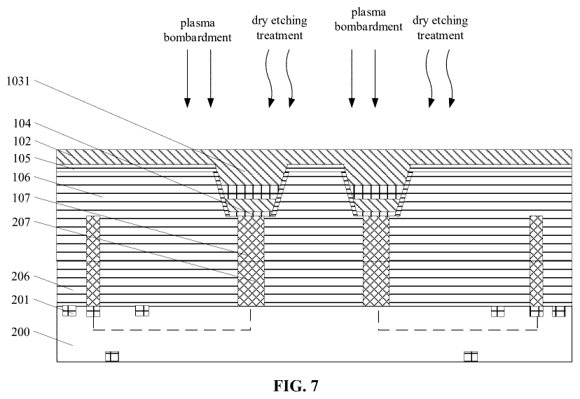

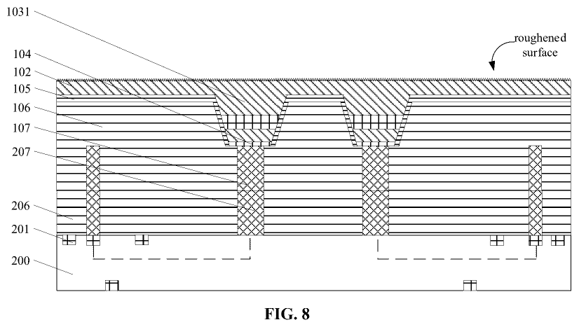

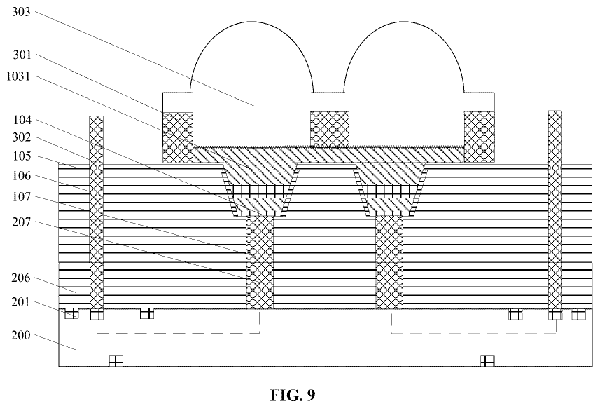

Please refer to FIG. 7 in combination with FIG. 8, the first bonding layer 106 and the second bonding layer 206 are bonded. The substrate 100 and the buffer layer 101 are removed from the second surface of the substrate 100 (see FIG. 5). And, the second surface of the first confinement layer 1031 is exposed. Then, the first gas and the second gas are introduced to roughen the second surface of the first confinement layer 1031, to obtain a roughened surface.

And, the second surface of the substrate 100 is opposite to the first surface of the substrate 100.

It should be pointed out that, in the embodiments of the present disclosure, the light emitting surface of the light emitting mesa may be the second surface of the first confinement layer 1031.

It should be understood that, the micro LED display chip including a light emitting mesa is not limited to the structure shown in FIG. 7. Thus, the light emitting surface of the light emitting mesa is not limited to the second surface of the first confinement layer 1031. For example, in another specific embodiment, it is also possible to form a second confinement layer, a quantum well layer and a first confinement layer from bottom to top on the first surface of the substrate to obtain a light emitting layer structure, instead of a method of invert etching for obtaining the light emitting layer structure described above. At this time, the light emitting surface of the light emitting mesa can be a front surface (corresponding to the first surface) of the first confinement layer.

In addition, the light emitting surface of the light emitting mesa is used for emitting light. Thus, for a light emitting mesa with other structures, its light emitting surface can also be a surface suitable for emitting light, and is not limited to the case where the light emitting mesa includes the first confinement layer.

Specifically, the driver chip 200 and the substrate 100 may be connected by flip bonding, and the first conductive column 107 and the second conductive column 207 are electrically connected in a one to one correspondence.

The first bonding layer 106 and the second bonding layer 206 may be bonded by adopting an appropriate bonding process, to realize flip bonding connection between the driver chip 200 and the substrate 100.

Here, the roughening treatment may include a physical plasma bombardment and a chemical dry etching treatment.

The first gas and the second gas are introduced, to perform the plasma bombardment on the light emitting surface (hereinafter referred to as the second surface of the first confinement layer 1031) using the first gas, and to perform the dry etching treatment on the second surface of the first confinement layer 1031 using the second gas, and the second surface of the first confinement layer 1031 has a surface roughness greater than or equal to a predetermined surface roughness threshold.

The surface roughness may include a combination of one or more selected from a group consisting of surface average roughness Ra and surface root mean square roughness Rq.

More specifically, the surface roughness threshold may be expressed by a single parameter, or by a weighted operation value (such as, weighted averaging, weighted summing, etc.) of multiple parameters.

In the embodiments of the present disclosure, by selecting an appropriate parameter to represent the surface roughness, a condition of the second surface of the first confinement layer 1031 can be accurately determined, which helps to determine an appropriate process objective to improve performance of a formed semiconductor structure.

In the embodiments of the present disclosure, by introducing the first gas and the second gas at the same time, to perform the bombardment and the etching treatment on the second surface of the first confinement layer 1031, the second surface of the first confinement layer 1031 has a surface roughness greater than or equal to the predetermined surface roughness threshold. With the above embodiment, the optical path can be adjusted by roughening the light emitting surface, and the propagation direction of the original total reflected light can even be changed, and thus, the probability of photons' escape is effectively increased, and the light extraction efficiency is improved. In addition, the bombardment and the etching treatment are both dry treatments, which have better morphological controllability and better process stability than a wet roughening process. The bombardment and the etching treatment are mature and stable processes in terms of process cost control, and thus have lower process costs and complexity than those of a roughening process using nanocrystals and nanoparticles as masks.

It should be pointed out that, a plasma etching machine can include an RF power supply controlled by an automatic matching network, connecting wound solenoid, and the solenoid generates an inductively coupled electric field. Under an action of the electric field, the etching gas glow discharge generates high-density plasma. Amount of power directly influences an ionization rate of the plasma, and influences density of the plasma in turn.

And, the inductively coupled plasma (ICP) power can also be referred as upper power. By adjusting the ICP power, the number of ions obtained from ionized plasma in a process chamber can be adjusted.

And, the radio frequency (RF) power can also be referred to as lower power. By adjusting the RF power, ion energy when the plasma in the process chamber bombards the substrate 100 can be adjusted.

In some embodiments, a second RF power is adopted during a process of performing the plasma bombardment on the light emitting surface using the first gas and performing the dry etching treatment on the light emitting surface using the second gas, and a first RF power is adopted during a process of etching, from the first surface of the substrate, the part of the thickness of the first confinement layer; and the second RF power is less than the first RF power.

And, the process of etching, from the first surface of the substrate 100, the part of the thickness of the first confinement layer can refer to the etching process shown in FIG. 3.

In the roughening process shown in FIG. 7, a smaller RF power is adopted, compared with the etching process shown in FIG. 3.

In the embodiments of the present disclosure, compared with an etching process for the first surface of the first confinement layer 1031 in a process of forming the light emitting mesa 103 (see FIG. 3), a small RF power is adopted in a roughening process of the second surface of the first confinement layer 1031, and ion energy during the plasma bombardment can be reduced, and intensity of a physical bombardment of plasma can be reduced. Excessive physical bombardment may cause that the second surface of the first confinement layer 1031 is bombarded and flattened, and adopting a small RF power will increase a particle size obtained after roughening, making it rougher and more uneven. In addition, a roughening treatment process in the embodiments of the present disclosure includes two parts of physical bombardment and chemical etching, and thus, reducing the physical bombardment intensity is also equivalent to increasing intensity of the chemical dry etching treatment, which is conducive to further improving controllability and treatment effect of the roughening treatment.

Further, a ratio of the first RF power to the second RF power may range in [10, ∞]; and/or, the second RF power ranges from 0 W to 10 W.

In one specific embodiment, the first RF power may range in [150 W, 230 W], for example, may be 190 W, and the second RF power may range in [0, 5 W], for example, may be 0.

In the embodiments of the present disclosure, the ratio of the first RF power to the second RF power ranges in [10, ∞]; and/or, the second RF power ranges from 0 W to 10 W, and the second RF power is very small, or even close to or equal to zero. By adopting a very small second RF power, ionic energy during the plasma bombardment can be minimized, the intensity of the physical bombardment of the plasma can be reduced, to further increase the particle size obtained after the roughening treatment, and improve controllability of the roughening treatment.

In some embodiments, steps for performing the plasma bombardment on the light emitting surface using the first gas may include ionizing the first gas with a second ICP power, to obtain plasma of the first gas; and using the plasma of the first gas to perform a plasma bombardment on the light emitting surface; and, a first ICP power is adopted during a process of etching, from the first surface of the substrate, the part of the thickness of the first confinement layer, and the second ICP power is greater than the first ICP power.

In the roughening process shown in FIG. 7, a greater RF power is adopted, compared with the etching process shown in FIG. 3.

Further, a ratio of the second ICP power to the first ICP power ranges in [2, 5]; and/or, the second ICP power ranges from 700 W to 1000 W.

In one specific embodiment, the first ICP power may range in [200 W, 320 W], for example, may be 260 W, and the second RF power may range in [800 W, 900 W], for example, may be 850 W.

In the embodiments of the present disclosure, compared with the etching process for the first surface of the first confinement layer 1031 in the process of forming the light emitting mesa, a relatively large ICP power is adopted in the roughening process of the second surface of the first confinement layer 1031, and thus, more gas molecules can be ionized into plasma. The roughening treatment process in the embodiments of the present disclosure includes two parts of physical bombardment and chemical etching, increasing the ICP power can increase the number of ions in the plasma, and decomposed plasma can react with atoms or molecules of the second surface of the first confinement layer 1031. As a result, this is equivalent to increasing the intensity of the chemical dry etching treatment, which is conducive to further improving controllability and treatment effect of the roughening treatment.

Further, the first gas may include argon gas, and the plasma of the first gas may be argon plasma.

In the embodiments of the present disclosure, the plasma of the first gas can be argon plasma, and because argon gas has high atomic mass and chemical stability, and can produce a microcrystalline structure with a more uniform size and higher precision, better bombardment effect can be obtained by bombarding using argon plasma.

It should be pointed out that, in the embodiments of the present disclosure, other appropriate gases, such as other inert gases other than argon, for example, nitrogen (N₂), may also be used as the first gas.

Further, a flow rate of argon gas should not be too small, otherwise argon plasma for bombardment will be too little; and the flow rate of argon gas should not be too large, otherwise ratio of the second gas used for the etching treatment will be reduced, and intensity of chemical dry etching treatment will even be reduced.

In one specific embodiment, the flow rate of argon gas may range from 50 sccm to 110 sccm, for example, from 70 sccm to 90 sccm, for example, may be 80 sccm.

In some embodiments, the first confinement layer 1031 is an N-type Group III-V compound layer, and the second gas contains Cl₂ and does not contain BCl₃.

In one specific embodiment, the first confinement layer 1031 may be GaN, and the second gas may be Cl₂. The following chemical reaction formula may be used to perform the dry etching treatment on the light emitting surface using Cl₂:

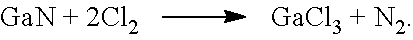

In the embodiments of the present disclosure, by using Cl₂, Group V atoms on a surface of the Group III-V compound layer (such as, nitrogen atoms on a surface of GaN) can be substituted by chlorine atoms, to be separated from a crystal lattice and form a Group V compound (such as, a nitride). Finally, the nitride and chloride can be separated from the surface of GaN together, to achieve an effect of GaN material being etched. In addition, by not containing BCl₃, the formed GaCl₃ can have a larger particle size and be rougher. Specifically, addition of BCl₃ will weaken a chemical factor in the etching process, thereby weakening selective etching of GaN and reducing a surface roughness of GaN.

In some embodiments, Cl₂ at a first flow rate is used as an etching gas during a process of etching, from the first surface of the substrate, the part of the thickness of the first confinement layer 1031, and Cl₂ in the second gas is at a second flow rate; and the second flow rate is less than the first flow rate.

In the roughening process shown in FIG. 7, a smaller flow rate of Cl₂ is adopted, compared with the etching process shown in FIG. 3.

Further, a ratio of the first flow rate to the second flow rate may range in [1, 4]; and/or, the second flow rate ranges from 30 sccm to 70 sccm.

In one specific embodiment, the first flow rate (i.e., the flow rate of Cl₂) adopted in the etching process shown in FIG. 3 may range from 100 sccm to 160 sccm, for example, from 120 sccm to 140 sccm, for example, may be 130 sccm.

It should be pointed out that, BCl₃ may also be introduced together in the etching process shown in FIG. 3.

In one non-limiting embodiment, a flow rate of BCl₃ may range from 1 sccm to 20 sccm, for example, from 8 sccm to 12 sccm, for example, may be 10 sccm.

Correspondingly, in the roughening process shown in FIG. 7, the second flow rate (i.e., the flow rate of Cl₂) may range from 40 sccm to 60 sccm, for example, may be 50 sccm.

In the specific implementation, compared with the etching process for the first surface of the first confinement layer 1031 in the process of forming the light emitting mesa, a relatively smaller flow rate of Cl₂ as the etching gas is adopted in the roughening process of the second surface of the first confinement layer 1031, to reduce a speed of a chemical reaction. A slow etching reaction further makes the formed GaCl₃ have a larger particle size and rougher.

Further, the roughened structure is a nanoscale microstructure; and the roughened structure has a width ranging from 20 nm to 1000 nm, and/or, a height ranging from 20 nm to 1000 nm.

Specifically, due to formation of the roughened structure, the surface roughness of the first confinement layer 1031 is relatively large. The width of the roughened structure is 20 nm to 1000 nm, and/or, the height of the roughened structure is 20 nm or 1000 nm, and the surface roughness obtained by the roughened structure can be more standardized and controllable.

Further, the roughened structure has a shape of one or more selected from a group consisting of spherical shape, hemispherical shape, conical shape, pointed-conical shape, cylindrical shape, and rectangular shape.

It should be pointed out that, the shape of the roughened structure can be not a standard shape, but can lie between two shapes, for example, an ellipsoid lying between a spherical shape and a hemispherical shape, and the like.

Please refer to FIG. 9, an N-type electrode 301 is formed. A P-type electrode 302 is formed to be electrically connected with the first conductive column 107. And, a microlens (Lens) 303 is formed on a treated second surface of the first confinement layer 1031.

Specifically, the N-type electrode 301 and the P-type electrode 302 may be made of conventional electrode materials, such as, conductive materials, such as appropriate metal materials, such as copper, tungsten, aluminum, platinum, silver, gold, and compound materials of various conductive materials, and the like.

And, the N-type electrode 301 may surround the light emitting mesa 103, and the P-type electrode 302 may be disposed in an edge region.

It should be pointed out that, in the embodiments of the present disclosure, plane layout (i.e., a position relationship shown in a top view) of the N-type electrode 301, the P-type electrode 302 and the microlens 303 is not limited.

The microlens 303 may be made of conventional lens materials, such as materials with a light transmittance greater than a predetermined light transmittance threshold.

In the embodiments of the present disclosure, the microlens 303 is formed on the treated second surface of the first confinement layer 1031, and the roughened second surface of the first confinement layer 1031, as a refractive layer of the light emitting mesa interface, better changes the propagation direction of the total reflected light, increases the probability of photons' escape, and improves the light extraction efficiency.

In the embodiments of the present disclosure, a micro LED display chip is further disclosed. As shown in FIG. 9, the micro LED display chip may include a light emitting mesa including a light emitting surface. The light emitting surface has a roughened structure prepared by the method for roughening a light emitting surface of a micro LED display chip described above.

Further, the roughened structure is a nanoscale microstructure; and the roughened structure has a width ranging from 20 nm to 1000 nm, and/or, a height ranging from 20 nm to 1000 nm.

As previously mentioned, by setting the width and/or height of the roughened structure, the surface roughness obtained by the roughened structure can be more standardized and controllable.

Further, the roughened structure has a shape of one or more selected from a group consisting of spherical shape, hemispherical shape, conical shape, pointed-conical shape, cylindrical shape, and rectangular shape.

It should be pointed out that, the shape of the roughened structure can be not a standard shape, but can lie between two shapes, for example, an ellipsoid lying between a spherical shape and a hemispherical shape, and the like.

Please refer to relevant description of the method for roughening a micro LED display chip mentioned above, for more information about the principle, specific implementation and beneficial effects of the micro LED display chip, which will not be repeated here.

It should be understood that, the term “and/or” herein is only an association that describes associated objects, and indicates that there can be three types of relationships. For example, A and/or B can be denoted as: A alone, A and B at the same time, and B alone. In addition, the character “/” herein indicates that related objects before and after is an “or” relationship. As used herein, unless expressly stated otherwise, the term “or” covers all possible combinations, except where infeasible. For example, if it is stated that a part may include A or B, then, unless expressly stated otherwise or infeasible, the part may include A, or B, or A and B. As a second example, if it is stated that a part may include A, B or C, then, unless expressly stated otherwise or infeasible, the part may include A, or B, or C, or A and B, or A and C, or B and C, or A and B and C.

The “plurality” herein refers to two or more.

Relational terms herein, such as, first, second, etc., are used only to distinguish an entity or operation from another entity or operation, without requiring or implying any actual relationship or sequence between those entities or operations. In addition, the words “including”, “having” and “containing” and other similar forms are intended to be equivalent in meaning and be open-ended, and item or items following any one of these words is not meant to be an exhaustive listing of such item or items, or to be limited to only the listed item or items.

It should be pointed out that, the sequence number of each step in the embodiments does not represent limitation of the execution order of each step.

In the foregoing specification, the embodiments have been described with reference to numerous specific details that can vary depending on the implementation. Certain changes and modifications may be made to the described embodiments. Other embodiments are clear in the art from consideration of the specification and practice of the present application disclosed herein. The description and examples are intended to be considered exemplary only, and a true scope and spirit of the present application are indicated by the following claims. The sequence of steps shown in FIGs is also intended for illustrative purposes only and is not intended to be limited to any particular sequence of steps. Therefore, it can be understood that these steps can be performed in a different sequence while implementing the same method.

In the drawings and specification, exemplary embodiments have been disclosed. However, many changes and modifications can be made to these embodiments. Therefore, although specific terms are employed, they are used only in a generic and descriptive sense and not for a purpose of limitation.

Although the present disclosure is disclosed as above, the present disclosure is not limited hereto. Various changes and modifications may be made without departing from the spirit and scope of the present disclosure. Therefore, the scope of protection of the present disclosure shall be subject to the scope limited by the claims.

What is claimed is:

1. A method for roughening a light emitting surface of a micro LED display chip, comprising:
providing a micro LED structure comprising a light emitting mesa, and the light emitting mesa has a surface comprising a light emitting surface; and
performing a plasma bombardment on the light emitting surface using a first gas, and performing a dry etching treatment on the light emitting surface using a second gas, to form a roughened structure on the light emitting surface.

2. The method for roughening a light emitting surface of a micro LED display chip according to claim 1, wherein a method for forming the light emitting mesa comprises:
providing a substrate and forming on a first surface of the substrate a first confinement layer, a quantum well layer and a second confinement layer;
etching, from the first surface of the substrate, the second confinement layer, the quantum well layer, and a part of a thickness of the first confinement layer, to obtain a light emitting mesa; and
removing the substrate from a second surface of the substrate, and exposing a second surface of the first confinement layer, wherein the second surface of the substrate is opposite to the first surface of the substrate.

3. The method for roughening a light emitting surface of a micro LED display chip according to claim 2, wherein before removing the substrate from the second surface of the substrate, the method for forming the light emitting mesa further comprises:
forming a first bonding layer covering the substrate and the light emitting mesa from the first surface of the substrate;
providing a driver chip with a second bonding layer on a first surface thereof; and
bonding the first bonding layer and the second bonding layer.

4. The method for roughening a light emitting surface of a micro LED display chip according to claim 2, wherein the method for forming the light emitting mesa further comprises:
forming a microlens on a treated second surface of the first confinement layer.

5. The method for roughening a light emitting surface of a micro LED display chip according to claim 2, wherein performing the plasma bombardment on the light emitting surface using the first gas, and performing the dry etching treatment on the light emitting surface using the second gas, to form the roughened structure on the light emitting surface, comprises:
introducing the first gas and the second gas, to perform the plasma bombardment on the light emitting surface using the first gas, and perform the dry etching treatment on the light emitting surface using the second gas, wherein the light emitting surface has a surface roughness greater than or equal to a predetermined surface roughness threshold.

6. The method for roughening a light emitting surface of a micro LED display chip according to claim 5, wherein a second RF power is adopted during a process of performing the plasma bombardment on the light emitting surface using the first gas and performing the dry etching treatment on the light emitting surface using the second gas, and a first RF power is adopted during a process of etching, from the first surface of the substrate, the part of the thickness of the first confinement layer; and the second RF power is less than the first RF power.

7. The method for roughening a light emitting surface of a micro LED display chip according to claim 6, wherein a ratio of the first RF power to the second RF power ranges in [10, ∞]; and/or, the second RF power ranges from 0 W to 10 W.

8. The method for roughening a light emitting surface of a micro LED display chip according to claim 5, wherein performing the plasma bombardment on the light emitting surface using the first gas comprises:
ionizing the first gas with a second ICP power, to obtain plasma of the first gas; and
using the plasma of the first gas to perform a plasma bombardment on the light emitting surface,
wherein a first ICP power is adopted during a process of etching, from the first surface of the substrate, the part of the thickness of the first confinement layer, and the second ICP power is greater than the first ICP power.

9. The method for roughening a light emitting surface of a micro LED display chip according to claim 8, wherein a ratio of the second ICP power to the first ICP power ranges in [2, 5]; and/or,
the second ICP power ranges from 700 W to 1000 W.

10. The method for roughening a light emitting surface of a micro LED display chip according to claim 5, wherein the first gas comprises argon gas, and the plasma of the first gas is argon plasma.

11. The method for roughening a light emitting surface of a micro LED display chip according to claim 5, wherein the first confinement layer is an N-type Group III-V compound layer, and the second gas contains Cl₂ and does not contain BCl₃.

12. The method for roughening a light emitting surface of a micro LED display chip according to claim 11, wherein the first confinement layer is made of GaN, and the following chemical reaction formula is used to perform the dry etching treatment on the light emitting surface using Cl₂:

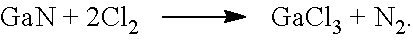

13. The method for roughening a light emitting surface of a micro LED display chip according to claim 11, wherein Cl₂ at a first flow rate is used as an etching gas during a process of etching, from the first surface of the substrate, the part of the thickness of the first confinement layer, and Cl₂ in the second gas is at a second flow rate;
wherein the second flow rate is less than the first flow rate.

14. The method for roughening a light emitting surface of a micro LED display chip according to claim 13, wherein a ratio of the first flow rate to the second flow rate ranges in [1, 4]; and/or,
the second flow rate ranges from 30 sccm to 70 sccm.

15. A micro LED display chip, comprising:
a light emitting mesa comprising a light emitting surface, and the light emitting surface has a roughened structure prepared by the method for roughening a light emitting surface of a micro LED display chip according to claim 1.

16. The micro LED display chip according to claim 15, wherein the roughened structure is a nanoscale microstructure; and the roughened structure has a width ranging from 20 nm to 1000 nm, and/or, a height ranging from 20 nm to 1000 nm.

17. The micro LED display chip according to claim 15, wherein the roughened structure has a shape of one or more selected from a group consisting of spherical shape, hemispherical shape, conical shape, pointed-conical shape, cylindrical shape, and rectangular shape.

18. A micro LED display chip, comprising:
a light emitting mesa comprising a light emitting surface, and the light emitting surface has a roughened structure of a nanoscale microstructure;
wherein the roughened structure has a width ranging from 20 nm to 1000 nm, and/or, a height ranging from 20 nm to 1000 nm.
